(19) United States
(12) Patent Application Publication
(10) Pub. No.: US 2023/0381911 A1
(43) Pub. Date: Nov. 30, 2023

(54) POLISHING METROLOGY

(71) Applicant: Taiwan Semiconductor Manufacturing Company, Ltd., Hsinchu (TW)

(72) Inventors: Chih Hung CHEN, Hsinchu City (TW); Kei-Wei CHEN, Tainan City (TW); Syun-Ming Jang, Hsin-Chu (TW)

(73) Assignee: Taiwan Semiconductor Manufacturing Company, Ltd., Hsinchu (TW)

(21) Appl. No.: 17/898,163

(22) Filed: Aug. 29, 2022

Related U.S. Application Data
(60) Provisional application No. 63/365,304, filed on May 25, 2022.

(51) Int. Cl. B24B 37/013; H01L 21/306; H01L 21/66

(52) U.S. Cl. CPC B24B 37/013; H01L 21/30625; H01L 22/26

(57) ABSTRACT

Methods and system for chemical mechanical polishing (CMP) are provided. A method may include performing a CMP process by contacting a polishing pad and a substrate at an interface. During the CMP process, the method includes measuring a force on the polishing pad at the interface to obtain force measurement values. Also, the method includes determining when the CMP process is complete based on the force measurement values.

### CROSS-REFERENCE TO RELATED APPLICATION

This application claims the benefit of priority to U.S. provisional patent application Ser. No. 63/365,304, filed on May 25, 2022, titled “POLISHING METROLOGY”, the contents of which are herein incorporated by reference in their entirety.

### BACKGROUND

Semiconductor devices are used in a variety of electronic applications, such as personal computers, cell phones, digital cameras, and other electronic equipment. The semiconductor industry continues to improve the integration density of various electronic components (e.g., transistors, diodes, resistors, capacitors, etc.) by continual reductions in minimum feature size, which allows more components to be integrated into a given area. These smaller electronic components also require smaller packages that utilize less area than the packages of the past, in some applications.

During the manufacturing of the semiconductor devices, various processing steps are used to fabricate integrated circuits on a semiconductor wafer. Generally, the processes include a chemical mechanical polishing (CMP) process for planarization of semiconductor wafers, thereby helping to provide more precisely structured device features on the ICs. The CMP process is a planarization process that combines chemical removal with mechanical polishing. The CMP process is a favored process because it achieves global planarization across the entire wafer surface. The CMP polishes and removes materials from the wafer, and works on multi-material surfaces. Furthermore, the CMP process avoids the use of hazardous gasses, and/or is usually a low-cost process.

One problem associated with CMP is end point detection, i.e., the point at which the target material is exposed. In the past, the end point has been detected by interrupting the CMP process, removing the wafer from the polishing apparatus, and physically examining the wafer surface by techniques which ascertain film thickness and/or surface topography. If the wafer does not meet specifications, it must be loaded back into the polishing apparatus for further planarization. If excess material has been removed, the wafer may not meet specifications and will be substandard. This end point detection method is time consuming, unreliable, and costly.

Although numerous improvements to end point detection during CMP have been invented, they have not been entirely satisfactory in all respects. Consequently, it would be desirable to provide a solution to maintain the reliability and the efficiency of the CMP process.

### BRIEF DESCRIPTION OF THE DRAWINGS

Aspects of the present disclosure are best understood from the following detailed description when read with the accompanying figures. It should be noted that, in accordance with the standard practice in the industry, various features may not be drawn to scale. In fact, the dimensions of the various features may be arbitrarily increased or reduced for clarity of discussion.

FIG. 1 is a perspective view schematic of a chemical mechanical polishing (CMP) metrology system, in accordance with some embodiments.

FIG. 2 is a perspective view schematic illustrating a sensor on the platen of the system of FIG. 1, in accordance with some embodiments.

FIG. 3A is an overhead view of the top surface of the platen of FIG. 2, in accordance with some embodiments.

FIGS. 3B-3E are overhead views of platens provided with a plurality of sensors, in accordance with some embodiments.

FIG. 4 is an overhead view of a portion of a polishing pad overlying a sensor on a platen, such as shown in FIG. 2, in accordance with some embodiments.

FIG. 5 is a cross sectional view of the polishing pad, sensor, and platen taken along line 5-5 in FIG. 4, in accordance with some embodiments.

FIG. 6 is an overhead view of a polishing pad overlying a sensor on a platen, such as shown in FIG. 2, in accordance with some embodiments.

FIGS. 7 and 8 are overhead views of portions of a polishing pad overlying a plurality of sensors on a platen in accordance with some embodiments.

FIG. 9 is a cross sectional view of the wafer 15 of FIG. 1 at an intermediate stage during a CMP process in accordance with some embodiments.

FIG. 10 is a two-dimensional graph illustrating the local friction force at locations of the wafer in accordance with some embodiments.

FIG. 11 is a three-dimensional graph illustrating the local friction force at locations of the wafer in accordance with some embodiments.

FIG. 12 is a flow chart illustrating a method in accordance with some embodiments.

FIG. 13 is a flow chart illustrating a method in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting.

For the sake of brevity, known techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many known processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

In addition, the present disclosure may repeat reference numerals and/or letters in the various examples. This repetition is for the purpose of simplicity and clarity and does not in itself dictate a relationship between the various embodiments and/or configurations discussed.

Certain embodiments herein involve chemical mechanical polishing (CMP) and CMP metrology. CMP is a method of planarizing or flattening out a semiconductor wafer surface by polishing away a thin layer of wafer surface. Typically, a CMP process polishes away surface layer material until a different lower layer material is exposed. When the two layers are different materials that exhibit different friction forces during polishing, polishing friction may be monitored to determine the exact time when the lower layer material is exposed. A resulting signal may be used as “end point” to stop polishing.

Various embodiments herein provide for a chemical/mechanical polishing (CMP) process for polishing or planarizing a wafer with a polishing pad, wherein the end point of the CMP process, i.e., the polishing level at which the target material is sufficiently exposed and the process is complete, is determined by measuring a force on the polishing pad to monitor frictional force at the interface between the polishing pad and the wafer.

In certain embodiments, a force at the surface of the polishing pad is directly measured. In certain embodiments, the force includes a friction force component in a direction tangential to the rotation of the polishing pad. Further, in certain embodiments, the force includes a normal force, i.e., the force is a normal force or includes a normal force component. Direct measurement of a force at the surface of the polishing pad eliminates signal noise and other issues with indirect measurements, such as those obtained by monitoring platen motor power (torque). For example, processes that use motor power consumption as an indirect measurement of friction may experience signal noise as motor power consumption is affected by many variables, such as polishing friction, diamond conditioning (to continuously refresh polishing pad) friction, motor bearing friction (increases as bearing wears), wafer location with respect to motor rotation center, motor speed, etc.

Various embodiments herein provide for obtaining a plurality of local force measurements at a surface of a CMP polishing pad during a CMP process. Such measurements can be used to create a two-dimensional (2D) map or a three-dimensional (3D) map indicative of friction at the pad/wafer interface across the wafer over time. The measurements may be used to indicate process end-point and/or to indicate polish uniformity. In certain embodiments, feedback on the polishing profile is provided during the CMP process, and tool settings are adjusted to better planarize or flatten out the polish profile.

Use of a plurality of localized force measurements provides for more precise monitoring as compared to using one value as an average for a whole wafer. When using average friction for whole wafer, signal sensitivity is reduced complicating determination of the exact point of complete surface film removal. Due to the use of localized force measurements in embodiments herein, the friction signal magnitude is magnified and the CMP process may be better controlled.

In order to provide localized force measurements, one or more sensors is located at the polishing pad/wafer interface. In certain embodiments, an array of sensors is provided in a desired pattern to increase data density for creation of the signal. An increased number of sensors may better support a map of the polish profile.

Further, embodiments herein provide for use of dedicated sensors for measuring the force that the polishing pad/wafer interface. A “dedicated sensor” has a single purpose, only the measurement of the force at the interface. The dedicated sensor does not provide any signal other than the force signal.

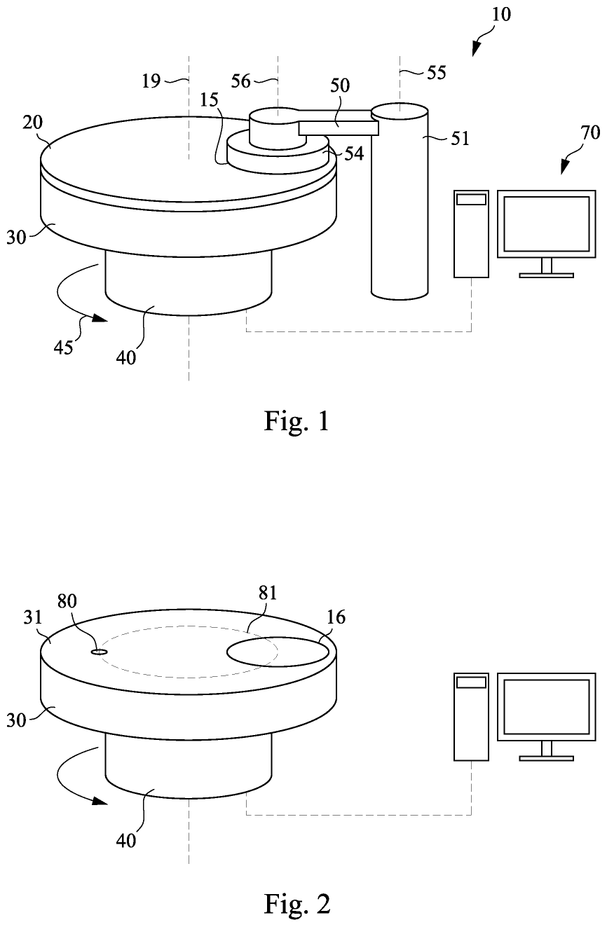

FIG. 1 is a schematic view of a Chemical Mechanical Polishing (CMP) system 10 as a CMP process is performed. The CMP system 10 is configured for performing a CMP process on a wafer 15 in a semiconductor manufacturing process.

In certain embodiments, the CMP system 10 includes a polishing pad 20, a platen 30, a platen motor 40, a wafer holder assembly 50 and a controller 70, in accordance with some embodiments. The elements of the CMP system 10 can be added to or omitted, and the disclosure should not be limited by the embodiments. For example, in certain embodiments the CMP system 10 may include an atomizer, a slurry dispenser, and a conditioning assembly.

The platen 30 is configured to receive and rotate the polishing pad 20 about a center axis 19. In some embodiments, the platen 30 is circular in shape. The diameter of the platen 30 lies in a range that is substantially larger than the diameter of the wafer 15 to be polished.

The platen motor 40 rotates the platen 30 in the direction of arrow 45 about the axis 19. As shown, the platen motor 40 is electrically connected to the controller 70 and may be actuated and operated by the controller 70.

In certain embodiments, the polishing pad 20 is fixed onto the platen 30. The polishing pad 20 may be a consumable item used in a semiconductor wafer fabrication process. In certain embodiments, the polishing pad 20 may be a hard, incompressible pad or a soft pad. For oxide polishing, hard and stiffer pads are generally used to achieve planarity. Softer pads are generally used in other polishing processes to achieve improved uniformity and a smooth surface. The hard pads and the soft pads may also be combined in an arrangement of stacked pads for customized applications.

The wafer holder assembly 50 is used to support the wafer 15. In some embodiments, as shown in FIG. 2, the wafer holder assembly 50 includes a shaft 51 with a driving motor, and a carrier head 54. The driving motor may be configured to control the movement of the carrier head 54 about a rotation axis 55. In some embodiments, the driving motor is an electric motor which converts electrical energy into mechanical energy for driving the rotation of the shaft 51. In some embodiments, the shaft 51 is driven to be rotatable about the rotation axis 55 by an external force (e.g., frictional force generated between the polishing pad 20 and the wafer 15) that is applied to the shaft 51 no matter which operation state of the driving motor.

In some embodiments, the carrier head 54 is rotatable about a rotation axis 56 by another driving motor (not shown in figures). The rotation axis 56 is different from the rotation axis 55.

The carrier head 54 may include a retainer retaining ring having an annular shape and a hollow center. The wafer 15 may be placed in the hollow center of retaining ring during the CMP process.

In one or more examples, the controller 70 includes or may be implemented in a computer including hardware, software, firmware, or any combination thereof. If implemented in software, the functions may be stored as one or more instructions or code on a computer-readable medium and executed by a hardware-based processing unit. Computer-readable media may include non-transitory computer-readable media, which corresponds to a tangible medium such as data storage media (e.g., RAM, ROM, EEPROM, flash memory, or any other medium that can be used to store desired program code in the form of instructions or data structures and that can be accessed by a computer).

Instructions may be configurable to be executed by one or more processors, such as one or more digital signal processors (DSPs), general purpose microprocessors, application specific integrated circuits (ASICs), field programmable logic arrays (FPGAs), or other equivalent integrated or discrete logic circuitry, included in controller 70. Accordingly, the term “processor” as used herein may refer to any of the foregoing structure or any other physical structure suitable for implementation of the described techniques. Also, the techniques could be fully implemented in one or more circuits or logic elements.

Techniques and technologies may be described herein in terms of functional and/or logical block components, and with reference to symbolic representations of operations, processing tasks, and functions that may be performed by various computing components or devices. Such operations, tasks, and functions are sometimes referred to as being computer-executed, computerized, software-implemented, or computer-implemented. It should be appreciated that the various block components shown in the figures may be realized by any number of hardware, software, and/or firmware components configured to perform the specified functions. For example, an embodiment of a controller, system, or a component may employ various integrated circuit components, e.g., memory elements, digital signal processing elements, logic elements, look-up tables, or the like, which may carry out a variety of functions under the control of one or more microprocessors or other control devices.

As described above, embodiments herein provide for measuring a force, such as a normal force, on the polishing pad 20 from the wafer 15. FIG. 2 illustrates how such a measurement is obtained.

FIG. 2 is a perspective view of the platen 30 and platen motor 40, with the polishing pad 20 removed so that the top surface 31 of the platen 30 may be viewed. As shown, a sensor 80 is located on the top surface 31 of the platen 30 where the polishing pad 20 is fixed. In certain embodiments, the sensor 80 is embedded in the platen 30. When assembled the sensor 80 lies under the polishing pad 20. In certain embodiments, the sensor 80 and the polishing pad 20 are adhered to the platen 30, such as with a pressure sensitive adhesive.

As shown, when the platen motor 40 rotates the platen 30 in the direction of arrow 45, the sensor 80 travels along a path 81 that passes under the location 16 of when the wafer 15 is positioned during a CMP process. Thus, a local force from the wafer 15 onto the polishing pad 20 may be measured by the sensor 80. In certain embodiments, the sensor 80 will obtain a sequence of measurements from sequential positions along the path 81 under the location 16 of the wafer 15.

In certain embodiments, the sensor 80 is located mid-radius, i.e., about halfway from the center axis 19 to the edge of the platen 30, so that the sensor path 81 sweeps across the center of the wafer as shown.

In a certain embodiment, the sensor 80 is a force sensor such as a force transducer, for example a single axis loadcell, or other force measuring device. In certain embodiments, the sensor 80 may be a multi-axis loadcell, such as for measuring friction force in a direction tangential to the polishing rotation and for measuring a normal force to the polishing pad 20.

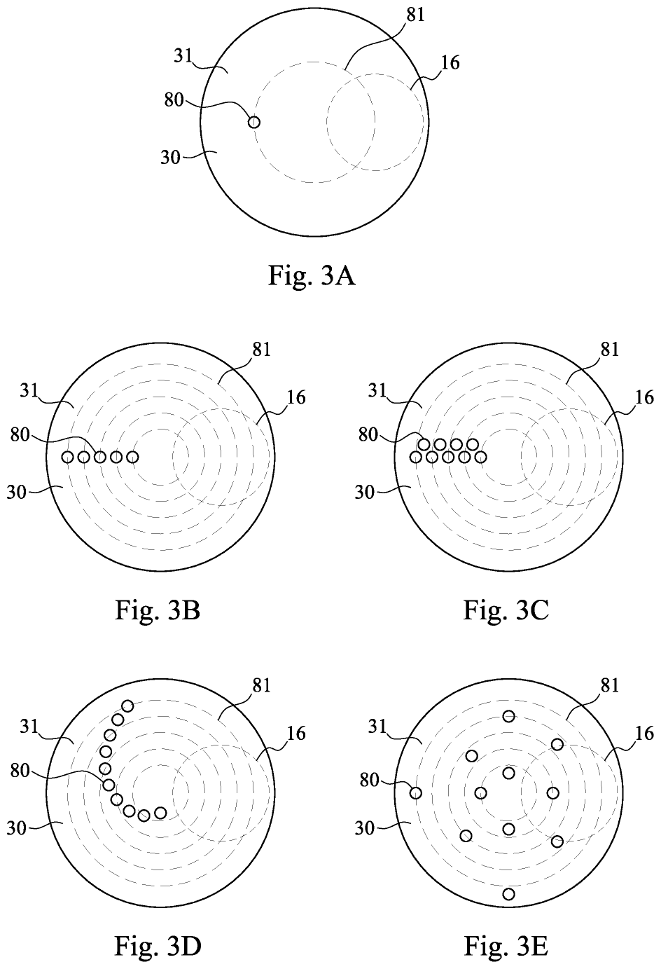

FIG. 3A is an overhead view of the top surface 31 of the platen 30 of FIG. 2. As shown, a single sensor 80 is located on the top surface 31.

In other embodiments, a plurality of sensors 80 are located on the top surface. The plurality of sensors 80 may be arranged in arrays of different designs, as shown in FIGS. 3B-3E. In FIG. 3B, a linear array of five sensors 80 is provided on the top surface 31.

In FIG. 3C, an overlapping array of two linear patterns totaling nine sensors 80 is provided on the top surface 31. In FIG. 3D, a spiral array of ten sensors 80 is provided on the top surface 31. In FIG. 3E, an evenly spaced array of eleven sensors 80 is provided on the top surface 31.

As can be seen in FIGS. 3B-3E, the plurality of sensors 80 may be arranged such that sensor paths 81 cross under the wafer location 16 to provide comprehensive data regarding force from every portion of the wafer 15. As with the embodiment with a single sensor, each sensor may obtain a sequence of measurements from sequential positions along the respective paths 81 under the location 16 of the wafer 15, at each position measuring a local force from the wafer 15 onto the polishing pad 20.

In certain embodiments, a sensor 80 may be located on top surface 31 with a soft polishing pad 20 overlying the sensor 80. However, other embodiments provide modified structures for local force measurement. Specifically, force measurement may be improved by providing the sensor-overlying portion of the polishing pad with sufficient freedom to move.

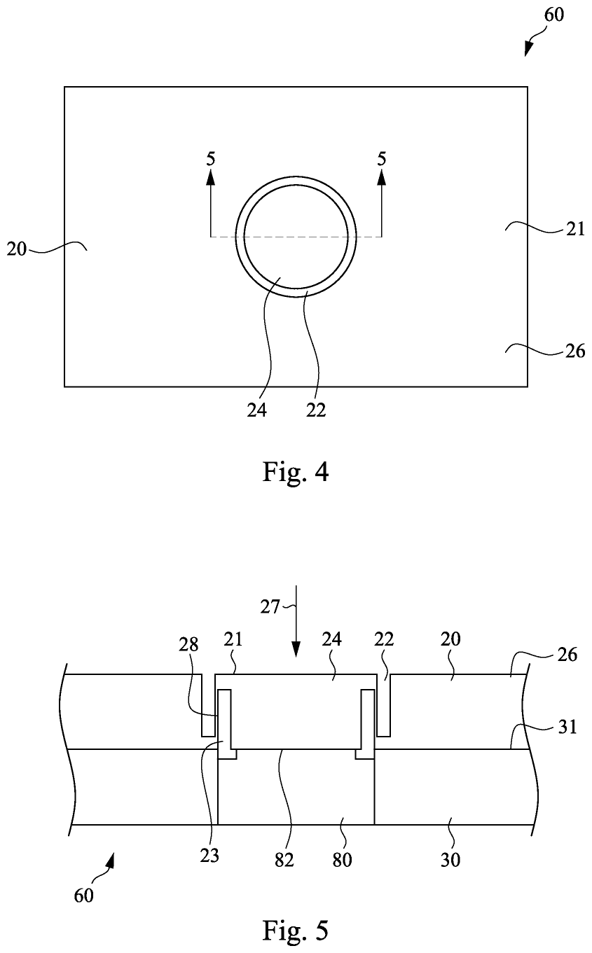

FIG. 4 provides an overhead view of a structure 60 of a polishing pad 20 lying over a sensor 80 formed on a platen 30 in accordance with certain embodiments. FIG. 5 provides a cross sectional view of the structure 60 taken along line 5-5 in FIG. 4.

Cross-referencing FIGS. 4 and 5, it may be seen that the overlying polishing pad 20 includes a top surface 21. Top surface 21 contacts and forms an interface with a wafer during a polishing process. As shown, the top surface 21 is formed with an interior groove or void 22. Further, the polishing pad 20 includes an island portion 24 located inside the interior void 22, and a base portion 26 in which the interior void 22 is formed, i.e., the base portion 26 surrounds the interior void 22. Thus, movement of the island portion 24 of the polishing pad 20 is not restricted by structural attachment to the main portion 26 of the polishing pad 20. In certain embodiments, the interior void 22 is empty. In other embodiments, the interior void 22 is filled with a compressible material, such as foam.

In certain embodiments, the island portion 24 may be completed separated and detached from the main portion 26. In the illustrated embodiment, as clearly shown in FIG. 5, the island portion 24 is not completely detached from the main portion 26 of the polishing pad 20. Keeping a minimal structural connection between the island portion 24 and the base portion 26 may facilitate pad installation.

As shown in FIG. 5, a thin bridge portion 28 connects the island portion 24 to the main portion 26, but does not limit movement of the island portion 24, particularly in the direction of arrow 27. As shown, the interior void 22 is positioned radially outward of another void 23, with the bridge portion 28 of the polishing pad 20 located between the two annular voids 22 and 23. In certain embodiments, the bridge portion 28 is annular and continuous such that the sensor 80 is sealed off from the voids 22 and top surface 21 where a polishing chemistry may be deposited or collect during a polishing process. As a result, the sensor lifetime may be extended.

The island portion 24 is located directly over the sensor 80, and may be fixed to the sensor 80. While the structure 60 of FIGS. 4 and 5 provides for movement of the island portion 24 of the pad 20 to allow the sensor 80 measure friction and/or a normal force on the island portion 24 other designs are contemplated and embodiments herein are not limited to structure 60 of FIGS. 4 and 5.

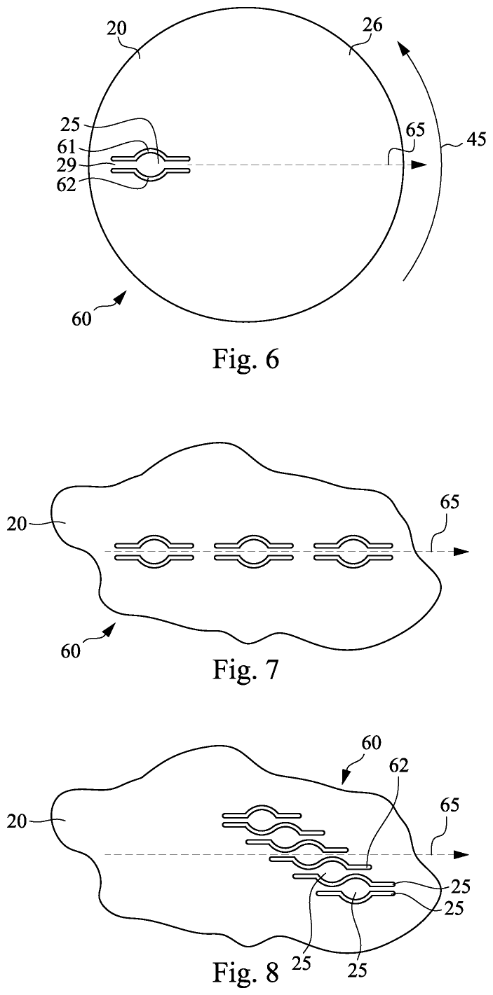

For example, FIG. 6 illustrates another possible structure 60 for allowing a sensor underlying a polishing pad 20 to locally measure friction and/or a normal force at a location on the polishing pad 20. In FIG. 6, two voids 61 and 62 are formed in the polishing pad 20 adjacent. As shown, a central paddle 25 is formed and is connected at opposite ends to the main portion 26 of the polishing pad 20 by thin bars 29. The central paddle 25 lies directly over and may be fixed to the sensor.

In certain embodiments, the thin bars 29 extend parallel to one another and along a radial direction 65 perpendicular to the tangential direction of the rotation 45. Further, in certain embodiments, the thin bars 29 connecting the sensor pad are flexible in the direction of polishing pad rotation, i.e., the direction of friction force tangential to the arrow 45. The amount of flexibility can be tuned by adjusting the bar shape. For example, flexibility can be increased by making the bars longer and/or thinner, i.e., by making portions of the voids 61 and 62 longer and/or closer together.

FIGS. 7 and 8 further illustrate portions of polishing pads 20 which include a plurality of structures 60. In FIG. 7, the structures 60 are align along the polishing pad 20 in about the radial direction 65.

In FIG. 8, a compact arrangement of structures 60 includes sharing voids 61 and 62 for multiple paddles 25. For example, void 61, labeled in FIG. 8, is located between and partially defines two different paddles 25. In the embodiment of FIG. 8, select paddles 25 may be aligned with radial direction 65 and other paddles 25 may be parallel to those select paddles 25.

Other designs of structures 60, and other arrangements or arrays of structures 60, are contemplated. Such structural 60 provide for communication of force through the polishing pad 20 to the sensor 80 by allowing local movement of a portion of the polishing pad lying over the sensor. Certain embodiments of structures 60 may completely detach an island portion of the polishing pad from the rest of the polishing pad to allow the island portion to “float”. Other embodiments may provide for a minimal structural connection to retain the island portion in position without impeding communication of force from the polishing pad to the sensor. In other embodiments, thin bars or other elements may connect a paddle to the rest of the polishing pad. Connections from the portion of the polishing pad to the rest of the polishing pad may be made through vertical structures (extending in a direction perpendicular to the plane of the polishing pad) and/or horizontal structures (extending in the direction of the plane of the polishing pad).

In various embodiments, and as shown in FIG. 5, the sensor 80 contacts the polishing pad 20 at a sensor/polishing pad interface 82. A force applied in the direction of arrow 27 on the top surface 21 of the polishing pad 20 at the location of the island portion 24 is communicated to the sensor 80 such that the sensor 80 may locally measure polishing friction.

The local friction value can determine if a particular region of wafer reaches the polish end-point first. For example, if the wafer center has slightly higher polish rate, the process will expose the lower level film at the wafer center first. Use of local friction sensors can map out the sequence of lower level film exposure across the wafer.

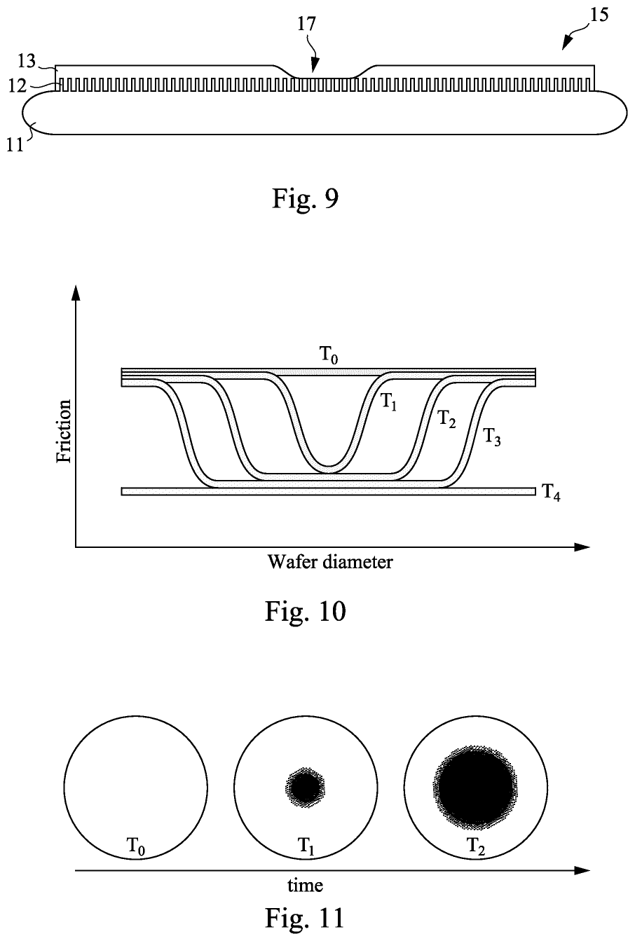

For example, FIG. 9 provides a cross sectional view of a wafer 15 during a CMP process. As shown, the wafer 15 includes a wafer substrate 11, a lower level film 12 or pattern, and a surface level film 13 to be polished. The CMP process is intended to remove the portion of the surface level film 13 at heights above the lower level film 12.

As shown in FIG. 9, the CMP process has removed a portion of the surface level film 13 and has reached the lower level film 12 at a central region 17 of the wafer 11.

If the lower level film 12 exhibits a greater frictional force under polishing than the surface level film 13, then local force measurements at the central region 17 of the wafer will increase when the CMP process reaches the lower level film 12.

Likewise, if the lower level film 12 exhibits a smaller frictional force under polishing than the surface level film 13, then local force measurements at the central region 17 of the wafer will decrease when the CMP process reaches the lower level film 12.

FIG. 10 is a two-dimensional graph illustrates the local friction force (along the Y-axis) at locations of the wafer, moving along the diameter from a left radial edge, to the center, to the right radial edge (along the X axis). Further, the graph illustrates that friction measurements were taken at five sequential times, T₀, T₁, T₂, T₃, and T₄.

In the embodiment graphed in FIG. 10, the friction force of the lower level film 12 is less than the friction force of the surface level film 13.

As shown, at time T₀, the friction at all areas of the wafer is at a same high level, indicated that the CMP polishing pad is in contact with the surface level film 13 at all locations measured by the sensors. At time T₁, the friction at the central region of the wafer diameter has decreased significantly, indicating that at central regions measured by the sensors the CMP polishing pad has come into contact with the lower level film 12. The status of the wafer at time T₁ may be illustrated by FIG. 9.

At time T₂, the central region where friction has decreased has grown to about a midway point between the wafer axis and the wafer radial edge, indicating that the CMP polishing pad has come into contact with the lower level film 12 at about half of the wafer.

At time T₃, the central region where friction has decreased has grown to almost the radial edge, indicating that the CMP polishing process is almost complete.

At time T₄, friction has decreased across the wafer to a lower level, indicating that the polish pad has reached the lower level film 12 across the wafer and that the CMP polishing process has been completed.

FIG. 10 illustrates how local friction data can be used to end polish time more precisely than an average value of a whole wafer. As shown, surface level film 13 is completely removed at time T₄. At time T₃, the wafer edge still has surface level film. Because the edge film occupies a low percentage of total wafer surface, the average friction signal would be similar between times T₄ and T₃, and may lead to an improper determination that the polishing process can be terminated. Utilizing the local friction measurements shows a large friction difference at the wafer edge. Thus, the determination reached using local friction measurements is more precise.

FIG. 11 provides a three-dimensional graph of the same data as FIG. 10 at times T₀, T₁ and T₂. As shown, the darker shaded region indicates a decrease in friction, i.e., that the surface level layer has been removed.

Local friction measurements can be used to map out the wafer polish profile. Therefore, embodiments herein provide for adjusting the polishing profile to minimize polish rate difference across the wafer.

Further, local friction measurements may indicate premature localized wear. In certain embodiments, the polishing process may be adjusted in response to such localized wear.

While FIGS. 9-11 illustrate quick polishing of a central region and edge film residue, this is merely an example of how the polishing process may proceed. In practice, the film residue may occur at other locations of the wafer.

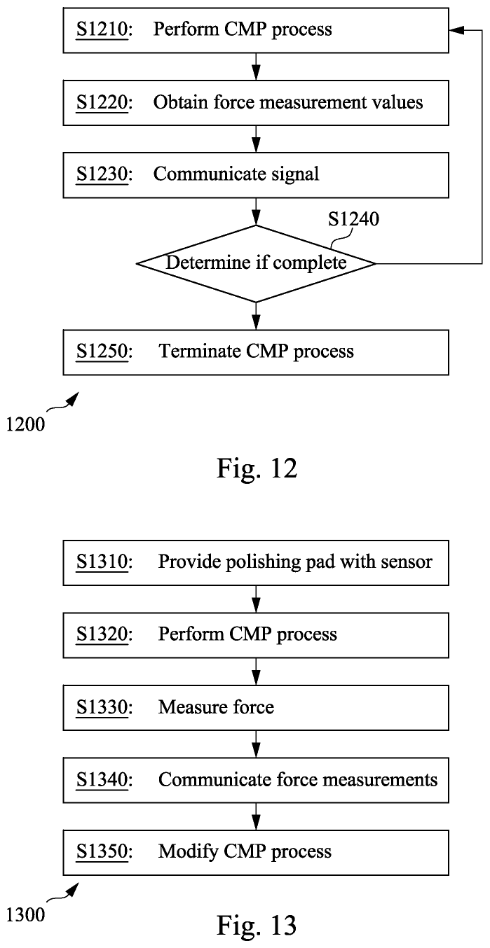

Referring now to FIG. 12, method 1200 is illustrated in a flow chart.

Method 1200 includes operation S1210, which includes performing a CMP process to polish a wafer.

Further, method 1200 includes measuring a force on the polishing pad to obtain force measurement values, while performing the CMP process, at operation S1220. In certain embodiments, a sensor locally measures forces to obtain local force measurements. In certain embodiments, a plurality of sensors is provided and the sensors locally measure forces to obtain local force measurements at a plurality of locations on the polishing pad to provide a plurality of local force measurement values.

Method 1200 may continue at operation S1230 with communicating a signal indicative of the force measurement value to a controller.

Method 1200 includes query S1240 which determines if the polishing process is complete based on the force measurement values. In a certain embodiment, the controller 70 of FIG. 1 receives the signals including data of force measurement values from the sensors. The controller may compile or otherwise process data from the signals and may provide a graph as described above. A change in friction across the surface of the wafer may be determined from the force measurement values and is used to determined that the polishing process is complete. In certain embodiments, determining when the CMP process is complete includes comparing current local force measurement values with previous local force measurement values. For example, determining when the CMP process is complete may include comparing a current local force measurement value from each sensor with a previous local force measurement value from the same respective sensor.

If the CMP process is not complete, method 1200 continues with operation S1210. When the CMP process is complete, method 1200 continues with operation S1250 wherein the CMP process is terminated. For example, the controller 70 may instruct the platen motor 40 to stop rotation of the platen 30 and polishing pad 20 thereon.

Referring now to FIG. 13, method 1300 is illustrated in a flow chart.

At operation S1310, method 1300 includes providing a polishing pad with a sensor for measuring a force at a location on the polishing pad. For example, the sensor may be located in a platen and the polishing pad may be mounted on the platen. Also, providing a polishing pad with a sensor for measuring a force at a location on the polishing pad may include forming a structure for allowing local movement of a portion of the polishing pad lying over the sensor.

Method 1300 may continue with operation S1320, which includes performing a chemical mechanical polishing (CMP) process by contacting a surface of the polishing pad with a wafer.

Method 1300 further includes measuring the force at the location on the polishing pad with the sensor to obtain force measurements at operation S1330.

Method 1300 may include communicating the force measurements from the sensor to a controller at operation S1340.

Further, at operation S1350, method 1300 includes modifying the CMP process based on the force measurements. For example, the controller may modify the CMP process based on the force measurements.

A method is provided in accordance with some embodiments. The method includes performing a chemical mechanical polishing (CMP) process by contacting a polishing pad and a substrate at an interface; during the CMP process, measuring a force on the polishing pad at the interface to obtain force measurement values; and determining when the CMP process is complete based on the force measurement values.

In certain embodiments of the method, the polishing pad comprises a force sensor at the interface to measure the force as a local force measurement value.

In certain embodiments of the method, the force sensor communicates a signal indicative of the force measurement value to a controller, and wherein the controller determines when the CMP process is complete based on the force measurement values.

In certain embodiments of the method, measuring the force on the polishing pad at the interface comprises locally measuring the force on the polishing pad at a plurality of locations on the polishing pad to provide a plurality of local force measurement values. In some embodiments of the method, determining when the CMP process is complete comprises comparing current local force measurement values with previous local force measurement values. In some embodiments, the polishing pad comprises a plurality of force sensors at the interface, wherein a respective force sensor is located at each location in the plurality of locations. In certain embodiments, each force sensor communicates a signal indicative of the local force measurement value to a controller, and the controller determines when the CMP process is complete based on the local force measurement values. In certain embodiments, the controller determines when the CMP process is complete by comparing a current local force measurement value from each force sensor with a previous local force measurement value from the same respective force sensor.

A method is provided in accordance with other embodiments. The method includes providing a polishing pad with a sensor for measuring a force at a location on the polishing pad; performing a chemical mechanical polishing (CMP) process by contacting a surface of the polishing pad with a wafer; measuring the force at the location on the polishing pad with the sensor to obtain force measurements; and modifying the CMP process based on the force measurements.

In certain embodiments of the method, providing the polishing pad with the sensor for measuring the force at the location on the polishing pad comprises locating the sensor in a platen and mounting the polishing pad on the platen. In certain embodiments, providing the polishing pad with the sensor for measuring the force at the location on the polishing pad further comprises forming a structure for allowing local movement of a portion of the polishing pad lying over the sensor.

In certain embodiments, the method includes communicating the force measurements from the sensor to a controller, and the controller modifies the CMP process based on the force measurements.

A chemical mechanical polishing (CMP) system is provided in accordance with certain embodiments. The CMP system includes a wafer holding mechanism configured to hold a wafer; a polishing pad having a top surface; a platen configured to rotate the polishing pad; and a sensor configured to directly measure a force at the top surface of the polishing pad.

In certain embodiments, the CMP system further includes a controller in communication with the sensor and configured to receive signals from the sensor including force measurement values, wherein the controller is configured to analyze the signals to monitor local changes in friction across the wafer.

In certain embodiments, the CMP system further includes a controller configured to control a polish time of the wafer, wherein the controller is configured to terminate a polishing process when a selected change in the force measured by the sensor is identified.

In certain embodiments of the CMP system, the sensor is configured to directly measure a local force at a location of the top surface of the polishing pad, and the method further includes a controller configured to control a polish time of the wafer, wherein the controller is configured to terminate a polishing process when a selected change in the local force measured by the sensor is identified.

In certain embodiments of the CMP system, the sensor is embedded in the platen.

In certain embodiments of the CMP system, the sensor has a surface, and the polishing pad directly contacts the surface of the sensor.

In certain embodiments, the CMP system further includes a structure for allowing local movement of a portion of the polishing pad lying over the sensor.

In certain embodiments, the CMP system includes a plurality of sensors, and each sensor is configured to directly measure a local force at a respective location on the top surface of the polishing pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present.

What is claimed is:

1. A method comprising:
performing a chemical mechanical polishing (CMP) process by contacting a polishing pad and a substrate at an interface;
during the CMP process, measuring a force on the polishing pad at the interface to obtain force measurement values; and
determining when the CMP process is complete based on the force measurement values.

2. The method of claim 1, wherein the polishing pad comprises a force sensor at the interface to measure the force as a local force measurement value.

3. The method of claim 2, wherein the force sensor communicates a signal indicative of the local force measurement value to a controller, and wherein the controller determines when the CMP process is complete based on the local force measurement values.

4. The method of claim 1, wherein measuring the force on the polishing pad at the interface comprises locally measuring the force on the polishing pad at a plurality of locations on the polishing pad to provide local force measurement values.

5. The method of claim 4, wherein determining when the CMP process is complete comprises comparing current local force measurement values with previous local force measurement values.

6. The method of claim 4, wherein the polishing pad comprises a plurality of force sensors at the interface, wherein a respective force sensor is located at each location in the plurality of locations.

7. The method of claim 6, wherein each force sensor communicates signals indicative of the local force measurement values to a controller, and wherein the controller determines when the CMP process is complete based on the local force measurement values.

8. The method of claim 7 wherein the controller determines when the CMP process is complete by comparing a current local force measurement value from each force sensor with a previous local force measurement value from a same respective force sensor.

9. A method comprising:
providing a polishing pad with a sensor for measuring a force at a location on the polishing pad;
performing a chemical mechanical polishing (CMP) process by contacting a surface of the polishing pad with a wafer;
measuring the force at the location on the polishing pad with the sensor to obtain force measurements; and
modifying the CMP process based on the force measurements.

10. The method of claim 9, wherein providing the polishing pad with the sensor for measuring the force at the location on the polishing pad comprises locating the sensor in a platen and mounting the polishing pad on the platen.

11. The method of claim 10, wherein providing the polishing pad with the sensor for measuring the force at the location on the polishing pad further comprises forming a structure for allowing local movement of a portion of the polishing pad lying over the sensor.

12. The method of claim 9, further comprising communicating the force measurements from the sensor to a controller, wherein the controller modifies the CMP process based on the force measurements.

13. A chemical mechanical polishing (CMP) system, comprising:
a wafer holding mechanism configured to hold a wafer;
a polishing pad having a top surface;
a platen configured to rotate the polishing pad; and
a sensor configured to directly measure a force at the top surface of the polishing pad.

14. The CMP system of claim 13, further comprising a controller in communication with the sensor and configured to receive signals from the sensor including force measurement values, wherein the controller is configured to analyze the signals to monitor local changes in friction across the wafer.

15. The CMP system of claim 13, further comprising a controller configured to control a polish time of the wafer, wherein the controller is configured to terminate a polishing process when a selected change in the force measured by the sensor is identified.

16. The CMP system of claim 13, wherein the sensor is configured to directly measure a local force at a location of the top surface of the polishing pad, and wherein the CMP system further comprises a controller configured to control a polish time of the wafer, wherein the controller is configured to terminate a polishing process when a selected change in the local force measured by the sensor is identified.

17. The CMP system of claim 13, wherein the sensor is embedded in the platen.

18. The CMP system of claim 13, wherein the sensor has a surface, and wherein the polishing pad directly contacts the surface of the sensor.

19. The CMP system of claim 13, further comprising a structure for allowing local movement of a portion of the polishing pad lying over the sensor.

20. The CMP system of claim 13, wherein the CMP system comprises a plurality of sensors, wherein each sensor is configured to directly measure a local force at a respective location on the top surface of the polishing pad.
